(19) United States
(12) Patent Application Publication
(10) Pub. No.: US 2018/0242730 A1
(43) Pub. Date: Aug. 30, 2018

(54) ENCLOSURE SYSTEM FOR ELECTRONIC EQUIPMENT CONCEALABLE IN A TABLE TOP

(71) Applicant: Jack Gershfeld, Fullerton, CA (US)

(72) Inventor: Jack Gershfeld, Fullerton, CA (US)

(21) Appl. No.: 15/443,049

(22) Filed: Feb. 27, 2017

(51) Int. Cl. A47B 21/06; H05K 7/14; H05K 5/02; H05K 5/03

(52) U.S. Cl. CPC A47B 21/06; H05K 7/1401; A47B 2021/068; H05K 5/0221; H05K 5/03; H05K 5/0226

(57) ABSTRACT

An enclosure system for electronic equipment concealable in a table top permits the user to selectively change the orientation of the enclosure by having two bezels nested in one another. A first bezel rests over an opening cut through a table top and a second bezel nests inside the first bezel. A saddle with a base and two vertical legs is attached to the second bezel. The enclosure tilts from a concealed position in which the top plate is flush with both the first and second bezel, to an open position in which the face plate of the enclosure is exposed. The saddle receives the enclosure in the concealed position between its base and vertical legs. The second bezel can be removed from the first bezel and re-oriented as desired.

### BACKGROUND OF THE INVENTION

This invention pertains to an enclosure system for electronic equipment, such as interconnect equipment for audio/visual presentation systems, concealable in a table top. Specifically, when not in use, a top plate of the enclosure system is flush with the table top, concealing audio, video, network and power connectors located in the face plate of the enclosure. When in use, the top plate tilts up exposing the connectors.

There is a need for an enclosure system for electronic equipment concealable in a table top permitting the user to orient multiple face plates with connectors in the desired directions and later easily change the orientation of the face plate as needed, and also to easily replace one face plate type with another.

### SUMMARY OF THE INVENTION

The present invention satisfies this need. The enclosure system comprises a first bezel resting over an opening cut through a table top and a second bezel nested inside the first bezel. A saddle with a base and two vertical legs is attached to the second bezel, defining an opening for receiving the enclosure in the concealed position. The saddle, together with the second bezel nested in the first bezel, are secured to the table top.

The enclosure can be selectively pivotally moved from a concealed position in which the top plate is flush with both the first and second bezels, to an open position in which the face plate and connectors therein are exposed. A leaf spring biases the enclosure towards the open position, while a latch selectively maintains the enclosure in the concealed position.

There are at least two positions in which the second bezel can be nested inside the first bezel, thus permitting the user to change the orientation of the face plate as needed.

BRIEF DESCRIPTION OF THE DRAWING FIGURES

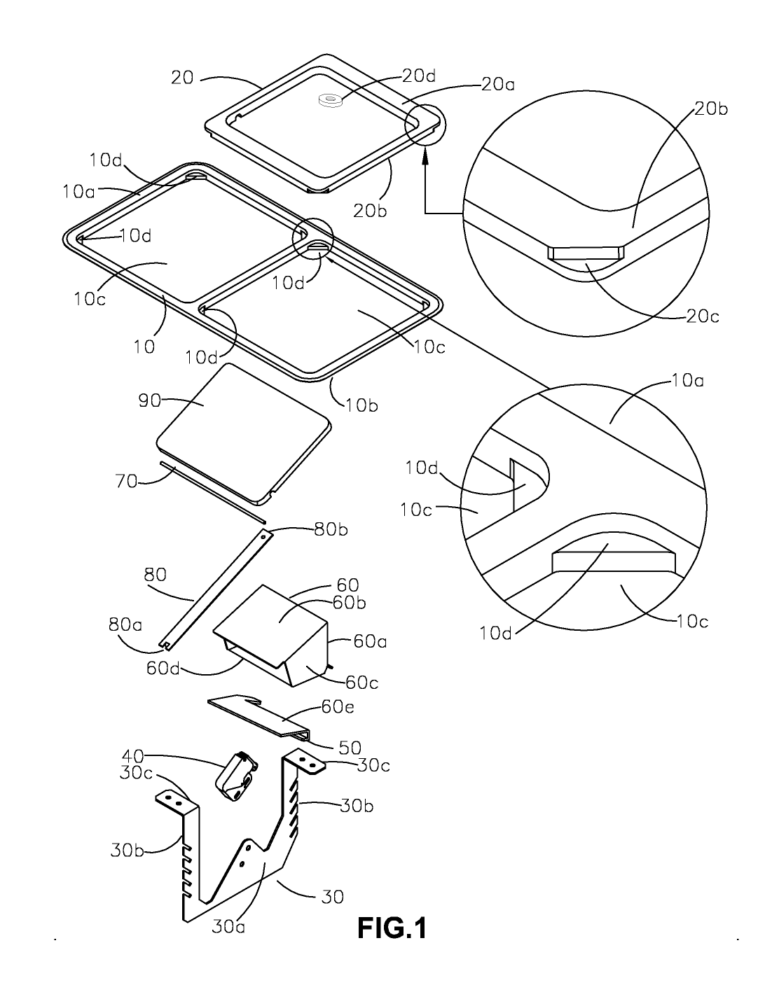

FIG. 1, in its left portion, shows exploded isometric view of the enclosure system according to the preferred embodiment of the present invention. FIG. 1, in its right portion, shows enlarged corners of the first and second bezels.

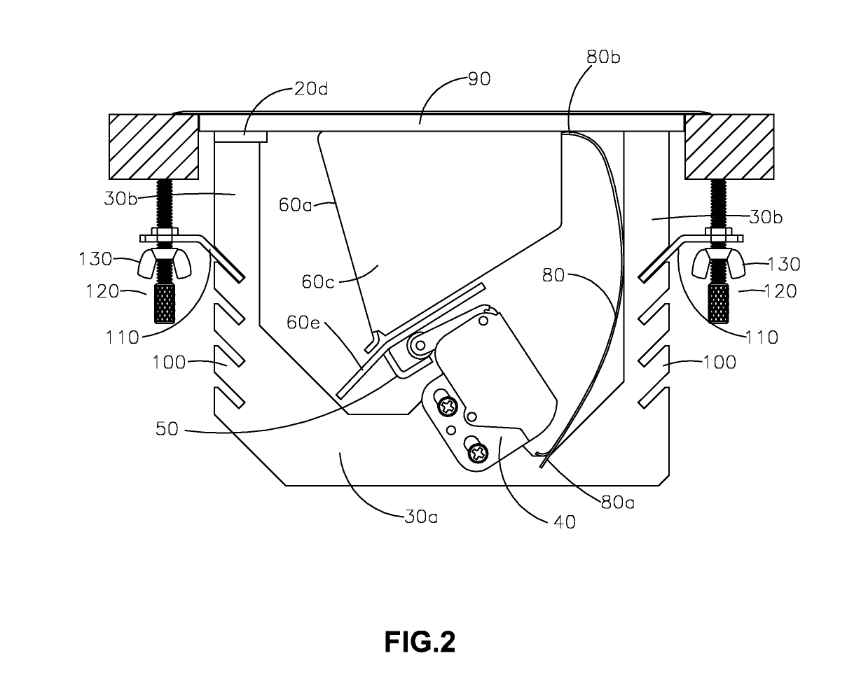

FIG. 2 shows elevational view thereof in the concealed position.

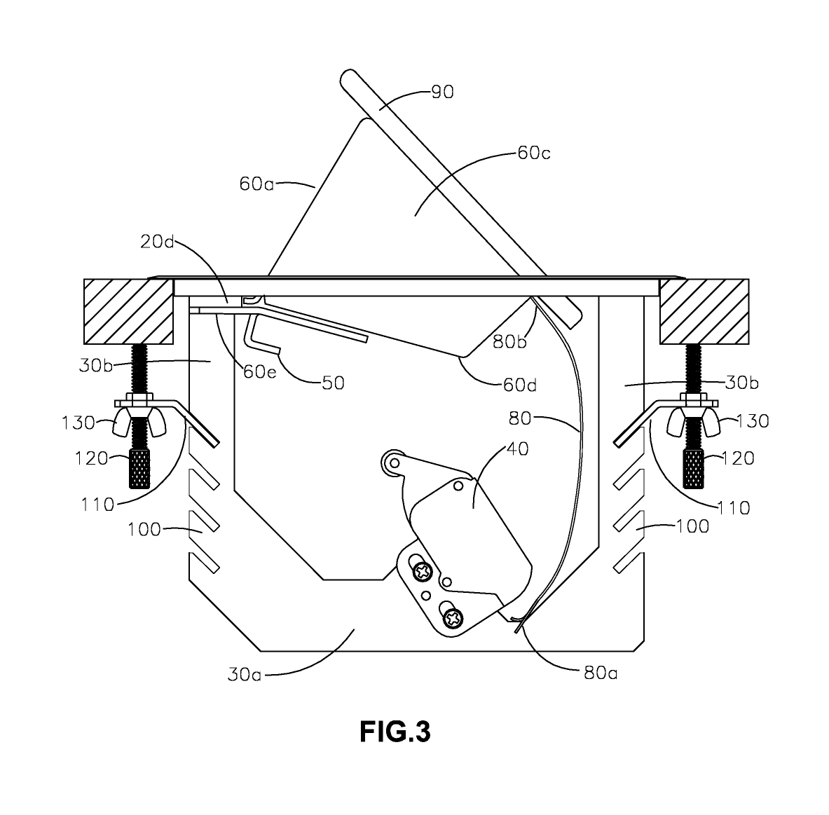

FIG. 3 shows elevational view thereof in the open position.

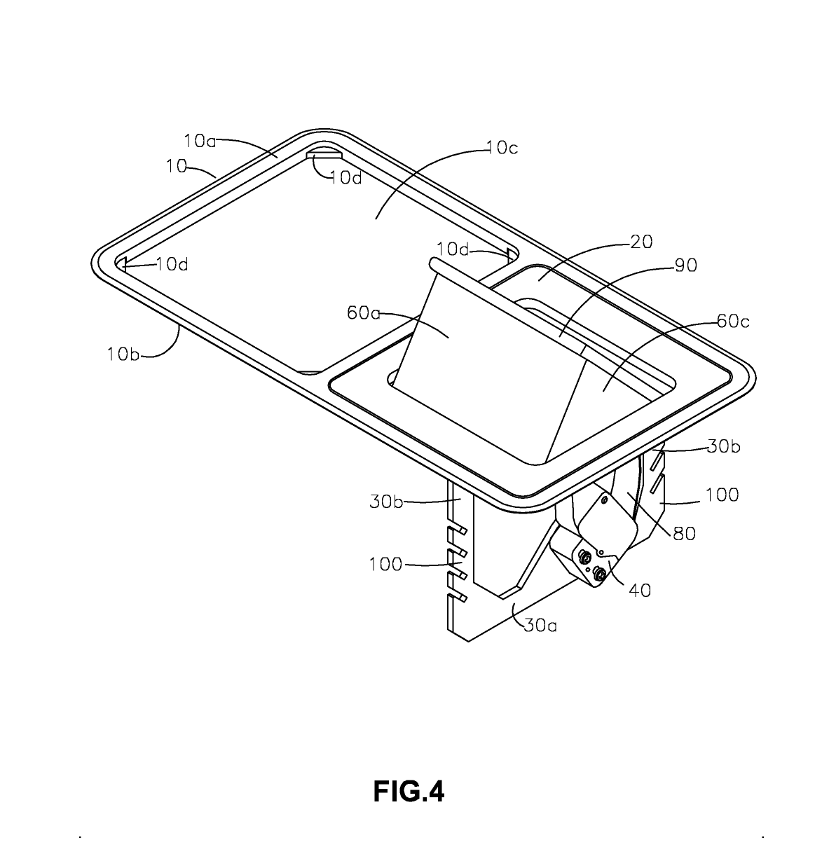

FIG. 4 shows isometric view thereof.

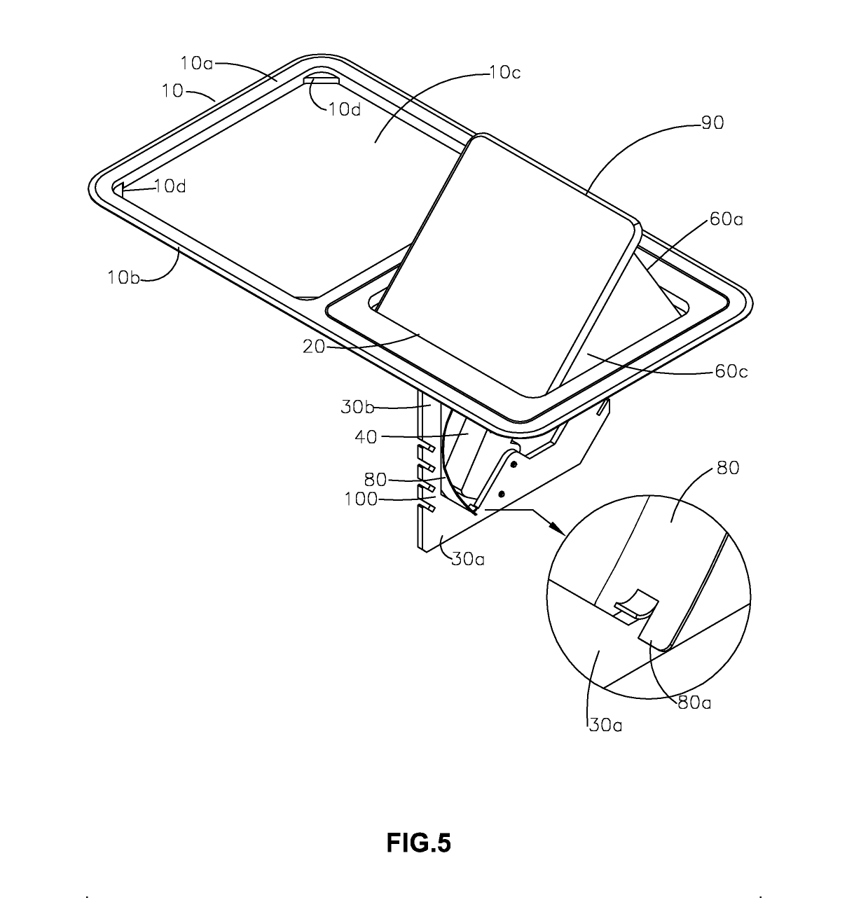

FIG. 5 shows isometric view thereof with an alternative orientation of the enclosure.

### DETAILED DESCRIPTION OF THE PREFERRED EMBODIMENT

This invention will be better understood with the reference to the drawing figures FIG. 1 through FIG. 5. The same numerals refer to the same elements in all drawing figures.

Viewing, simultaneously, FIG. 1 through FIG. 5, numeral 10 indicates a first bezel. First bezel 10 comprises a top surface indicated by numeral 10a and a bottom surface indicated by numeral 10b. Numeral 20 indicates a second bezel. Second bezel 20 comprises an upper surface indicated by numeral 20a and a lower surface indicated by numeral 20b.

Numeral 30 indicates a saddle. Numeral 40 indicates a latch. Numeral 50 indicates a hook. Numeral 60 indicates an enclosure. Enclosure 60 is suitable for housing electronic equipment. Enclosure 60 comprises a face plate indicated by numeral 60a, a top portion indicated by numeral 60b, two opposite side walls indicated by numeral 60c and a bottom portion indicated by numeral 60d. Face plate 60a contains various connectors, such as audio, video, network and power connectors. The connectors are not shown in FIG. 1 through FIG. 5.

Numeral 60e indicates a contact plate. Contact plate 60e is disposed on bottom portion 60d. Contact plate 60e extends outwardly on the side of face plate 60a.

Hook 50 is L-shaped with the opening of the “L” facing opposite to face plate 60a. Hook 50 is disposed on contact plate 60extending n from contact plate 60

Numeral 70 indicates a hinge. Numeral 80 indicates a leaf spring. Numeral 90 indicates a top plate. Top plate 90 is attached to top portion 60b.

First bezel 10 defines at least one rectangular opening indicated by numeral 10c. FIG. 1 through 5 show first bezel 10 defining two rectangular openings 10c, however, first bezel 10 can have two, three, four or more rectangular openings 10c.

First bezel 10 receives second bezel 20. An outer perimeter of bottom surface 10b rests on edges of an opening cut through a table top.

First bezel 10 comprises a separate lug projection member indicated by numeral 10d. Lug projection member 10d is disposed in each corner of rectangular opening 10c. Second bezel 20 comprises a separate recess indicated by numeral 20c. Recess 20c is disposed in each corner of lower surface 20b. Recess 20c io coincides with and receives lug projection member 10d, such that top surface 10a is flush with upper surface 20a. Both lug projection member 10d and recess 20c must be separate, as opposed to a continuous lug projection member running along the perimeter of rectangular opening 10c and/or a continuous recess running along the perimeter of lower surface 20b. This is necessary to enable the user to remove and reposition enclosure 60 without disconnecting any cables feeding audio, video, network and power connectors by reaching from under the table top, tilting enclosure 60 and pulling it down through rectangular opening 10c by clearing lug projection member 10d and recess 20c. Having a continuous lug projection member running along the perimeter of rectangular opening 10c and/or a continuous recess running along the perimeter of lower surface 20b prevents pulling enclosure 60 down through rectangular opening 10c.

Saddle 30 comprises a base indicated by numeral 30a and a pair of vertical legs indicated by numeral 30b. Vertical legs 30b extend up from opposite ends of base 30a and terminate in upper ends indicated by numeral 30c. Base 30a and vertical legs 30b define an open area receiving enclosure 60 therein. Upper ends 30c are attached lower surface 20b. In the preferred embodiment shown in FIG. 1 through FIG. 5, upper ends 30c are shown as flanges with openings for receiving screws for attachment lower surface 20b. Saddle 30 is preferably formed from sheet metal.

Top plate 90 is pivotally mounted to second bezel 20 by way of hinge 70. In the preferred embodiment, second bezel 20 and top plate 90 have bores receiving hinge 70 (not shown). Enclosure 60 moves, in a pivotal fashion about hinge 70, from a concealed position in which top plate 90 is flush with top surface 10a and upper surface 20a to an open position in which face plate 60a is exposed.

Latch 40 is disposed on base 30a, such that latch 40 selectively maintains enclosure 60 in the concealed position by way of engaging with hook 50.

At least one leaf spring 80 must be used, however, more leaf springs 80 can be added to increase the resilience of leaf spring 80. Leaf springs 80 are preferably made out of tampered blue spring steel.

Leaf spring 80 comprises a proximal end indicated by numeral 80a and a distal end indicated by numeral 80b. Proximal end 80a is formed as a U-shaped tongue straddling saddle 30 and gliding thereon. Distal end 80b is fixedly attached to enclosure 60 on the side of enclosure 60 opposite to face plate 60a. When enclosure 60 is in the open position, leaf spring 80 is substantially uncurled. Tilting enclosure 60 towards the concealed position causes leaf spring 80 to curl and acquire tension. Accordingly, leaf spring 80 is biasing enclosure 60 towards the open position. Specifically, FIG. 2 shows leaf spring 80 in tension when enclosure 60 is in the concealed position. FIG. 3 shows tension in leaf spring 80 released when enclosure 60 is in the open position.

In the preferred embodiment, latch 40 has a spring loaded roller engaging with hook 50. To launch enclosure 60 in the open position, the user would push on top plate 90 causing the spring loaded roller in latch 40 to disengage from hook 50. This will cause leaf spring 80 to push enclosure 60 up. To conceal enclosure 60, the user would push on top plate 90 until the spring loaded roller in latch 40 engages with hook 50.

Numeral 20d indicates a magnet. Magnet 20d is disposed on lower surface 20b, such that magnet 20d coincides with contact plate 60e. When enclosure 60 moves to the open position, contact plate 60e engages with magnet 20c and secures enclosure 60 in the open position.

Rectangular opening 10c is capable of receiving second bezel 20 in at least two positions. Thus, as selected by the user, enclosure 60 and face plate 60a therein can face at least two directions. Specifically, FIG. 4 and FIG. 5 show two alternative orientations of face plate 60a. In order to change the orientation of face plate 60a shown in FIG. 4, the user would remove second bezel 20 from first bezel 10 and re-insert it back with the orientation shown in FIG. 5.

Saddle 30 comprises a plurality of teeth indicated by numeral 100. Teeth 100 are disposed along outer edges of vertical legs 30b. Teeth 100 extend upwardly at a substantially forty five degree angle in relation to the table top. Teeth 100 define spaces therebetween adapted for insertion of holding plates indicated by numeral 110. Holding plates 110 are formed from strips of bent sheet metal and comprise openings adapted for receiving lag screws indicated by numeral 120. Lag screws 120 bias holding plates 110 in the direction opposite to a bottom of the table top, thereby securing saddle 30 to the table top.

Numeral 130 indicates wing nuts. Lag screws 120 are adapted for receiving wing nuts 130. Wing nuts 130 tighten lag screws 120 and prevent lag screws 120 from coining loose due to movements of the enclosure 60. FIG. 2 shows wing nuts 130 in the untightened position and FIG. 3 shows wing nuts 130 in the tightened position.

While the present invention has been described and defined by reference to the preferred embodiment of the invention, such reference does not imply a limitation on the invention, and no such limitation is to be inferred. The invention is capable of considerable modification, alteration, and equivalents in form and function, as will occur to those ordinarily skilled and knowledgeable in the pertinent arts. The depicted and described preferred embodiment of the invention is exemplary only, and is not exhaustive of the scope of the invention. Consequently, the invention is intended to be limited only by the spirit and scope of the appended claims, giving full cognizance to equivalents in all respects.

1. An enclosure system for electronic equipment concealable in a table top comprising:
a first bezel comprising a top surface and a bottom surface;
a second bezel comprising an upper surface and a lower surface;
a saddle;
a latch;
a contact plate;
a magnet;
a an L-shaped hook;
an enclosure suitable for housing electronic equipment and comprising a face plate, a top portion, two opposite side walls and a bottom portion;
a hinge;
one or more leaf springs;
a top plate attached to the top portion of the enclosure;
wherein the first bezel defining at least one rectangular opening receiving the second bezel, wherein an outer perimeter of the bottom surface is for resting on edges of an opening cut through a table top, the first bezel comprising a separate lug projection member disposed in each corner of said rectangular opening;
wherein the second bezel comprising a separate recess disposed in each corner of the lower surface, the recess coinciding with and receiving the lug projection member such that the top surface is flush with the upper surface;
wherein the saddle comprising a base, a pair of vertical legs extending up from opposite ends of the base and terminating in upper ends, the base and the vertical legs defining an open area receiving the enclosure therein, the upper ends attached to the lower surface;
wherein the top plate is pivotally mounted to the second bezel by way of the hinge for pivotal movement of the enclosure from a concealed position in which io the top plate is flush with the top surface and the upper surface to an open position in which the face plate is exposed;
wherein the magnet is disposed on the lower surface and the contact plate is disposed on the bottom portion, the contact plate extending outwardly on the side of the face plate and coinciding with the magnet, such that when the enclosure moves to the open position, the contact plate engaging with the magnet and securing the enclosure in the open position;
wherein the latch is disposed on the base and the hook is disposed on the contact plate, the hook extending down from the contact plate and facing opposite to the face plate, such that the latch selectively maintains the enclosure in the concealed position by way of engaging with the hook;
wherein the leaf spring comprising a proximal end formed as a U-shaped tongue straddling the saddle and gliding thereon and a distal end fixedly attached to the enclosure on the side of the enclosure opposite to the face plate, thereby biasing the enclosure towards the open position by curling and acquiring tension due to the enclosure moving towards the concealed position;
wherein the rectangular opening capable of receiving the second bezel in at least two positions, thus permitting the face plate to selectively face at least two directions;
wherein the enclosure capable of removal by way of pulling it down through the rectangular opening by way of tilting thereof and clearing the lug projection members and recesses.

2. An enclosure system as in claim 1, wherein the saddle further comprising a plurality of teeth disposed along outer edges of the vertical legs, the teeth extending upwardly at a substantially forty five degree angle in relation to the table top and defining spaces therebetween adapted for insertion of holding plates formed from strips of bent sheet metal and comprising openings adapted for receiving lag screws biasing the holding plates in the direction opposite to a bottom of the table top, thereby securing the saddle to the table top.

3. An enclosure system as in claim 2, wherein the lag screws are adapted for receiving wing nuts tightening the lag screws and preventing the lag screws from coining loose due to movements of the enclosure.

4. (canceled)

5. (canceled)

6. (canceled)
